(19) United States
(12) Patent Application Publication
(10) Pub. No.: US 2021/0359245 A1
(43) Pub. Date: Nov. 18, 2021

(54) ARRAY SUBSTRATE AND DISPLAY PANEL

(71) Applicant: Wuhan China Star Optoelectronics Semiconductor Display Technology Co., Ltd., Wuhan, Hubei (CN)

(72) Inventor: Shaojing Wu, Wuhan, Hubei (CN)

(73) Assignee: Wuhan China Star Optoelectronics Semiconductor Display Technology Co., Ltd., Wuhan, Hubei (CN)

(21) Appl. No.: 16/625,351

(22) PCT Filed: Oct. 21, 2019
(86) PCT No.: PCT/CN2019/112177

§ 371 Date: Dec. 20, 2019

(30) Foreign Application Priority Data
Jun. 21, 2019 (CN) 201910540560.9

(51) Int. Cl. H01L 51/52; H01L 27/32

(52) U.S. Cl. CPC H01L 51/5212; H01L 51/5253; H01L 27/3276

(57) ABSTRACT

An embodiment of the present invention discloses an array substrate and a display panel. The array substrate includes a base layer, a thin film transistor, auxiliary electrode, and an additional electrode. The thin film transistor, the auxiliary electrode, and the additional electrode are disposed on the base layer. The auxiliary electrode is disposed between the thin film transistor and the additional electrode. The auxiliary electrode is electrically connected to the additional electrode by an electrical connecting structure. The present solution improves luminous uniformity of the array substrate.

### FIELD OF INVENTION

The present invention relates to a field of display technologies, especially to an array substrate and a display panel.

### BACKGROUND OF INVENTION

Active-matrix organic light-emitting diode (AMOLED) display panels gradually become a display technology of new generation because of characteristics of high contrast, wide color gamuts, and low power consumption.

However, as a dimension of the AMOLED display panel gradually becomes greater and display resolution becomes higher, a length of a power cable of the display panel increases, a width thereof decreases, and a resistance of the cable increases. When a drive circuit transmits signals to a light-emitting unit, and voltage drop on the cable also increases, which results in different strengths of signals acquired by the light-emitting units with different distances from the drive circuit such that the display panel luminates unevenly.

### SUMMARY OF INVENTION

### Technical Issue

Because the power cable of the display panel has the decreased width and increased resistance, voltage drop also increases when the drive circuit transmits signals to the light-emitting units, the light-emitting units with different distances from the drive circuit acquires signals from the drive circuit with different strengths such that the display panel luminates unevenly.

### Technical Solution

An embodiment of the present invention provides an array substrate and a display panel that are able to improve luminous uniformity of the array substrate and the display panel.

In a first aspect, an embodiment of the present invention provides an array substrate, comprising: a base layer, a thin film transistor, an auxiliary electrode, and an additional electrode;

the thin film transistor, auxiliary electrode and the additional electrode disposed on the base layer, the auxiliary electrode disposed between the thin film transistor and the additional electrode, and the auxiliary electrode connected to the additional electrode by an electrical connecting structure.

In the array substrate provided by an embodiment of the present invention, the base layer comprises a base substrate and an inorganic insulation layer, the inorganic insulation layer is disposed on the base substrate.

In the array substrate provided by an embodiment of the present invention, the electrical connecting structure is covered and disposed in the inorganic insulation layer.

In the array substrate provided by an embodiment of the present invention, the array substrate further comprises:

a planarization layer, the planarization layer disposed on the thin film transistor, the auxiliary electrode, and the base layer, and a via hole defined in the planarization layer and exposing the auxiliary electrode; and

an anode layer, the anode layer disposed on the planarization layer and connected to the auxiliary electrode through the via hole.

In the array substrate provided by an embodiment of the present invention, the anode layer further comprises an anode extension portion; and

the anode extension portion is disposed on a side of the anode layer near the additional electrode and extends along a direction toward the additional electrode, and the anode extension portion covers the base layer and the additional electrode.

In the array substrate provided by an embodiment of the present invention, the anode extension portion is formed integrally with the anode layer and forms the electrical connecting structure.

In the array substrate provided by an embodiment of the present invention, the array substrate further comprises a crack detecting circuit; and

the crack detecting circuit is disposed on the base layer and is configured to detect whether the array substrate has a crack.

In the array substrate provided by an embodiment of the present invention, the additional electrode is disposed between the crack detecting circuit and the auxiliary electrode.

In the array substrate provided by an embodiment of the present invention, the array substrate further comprises a first blocking wall;

the first blocking wall is disposed on a side of the additional electrode near the crack detecting circuit and/or on a side of the additional electrode near the auxiliary electrode.

In the array substrate provided by an embodiment of the present invention, a thickness of the first blocking wall is greater than a thickness of the additional electrode.

In the array substrate provided by an embodiment of the present invention, the array substrate further comprises a second blocking wall;

the second blocking wall is disposed on a side of the anode layer toward the additional electrode or on a side of the anode extension portion near the additional electrode.

In the array substrate provided by an embodiment of the present invention, the thin film transistor is located on an edge of the base layer.

In a second aspect, an embodiment of the present invention provides a display panel, comprising: an array substrate; and

the array substrate comprising a base layer, a thin film transistor, an auxiliary electrode, and an additional electrode, the thin film transistor, auxiliary electrode and the additional electrode disposed on the base layer, the auxiliary electrode disposed between the thin film transistor and the additional electrode, and the auxiliary electrode connected to the additional electrode by an electrical connecting structure.

In a display panel provided by an embodiment of the present invention, the base layer comprises a base substrate and an inorganic insulation layer, and the inorganic insulation layer is disposed on the base substrate.

In a display panel provided by an embodiment of the present invention, the electrical connecting structure is covered and disposed in the inorganic insulation layer.

In a display panel provided by an embodiment of the present invention, the array substrate further comprises:

a planarization layer, the planarization layer disposed on the thin film transistor, the auxiliary electrode, and the base layer, and a via hole defined in the planarization layer and exposing the auxiliary electrode; and

an anode layer, the anode layer disposed on the planarization layer and connected to the auxiliary electrode through the via hole.

In a display panel provided by an embodiment of the present invention, the array substrate further comprises an anode extension portion; and

the anode extension portion is disposed on a side of the anode layer near the additional electrode and extends along a direction toward the additional electrode, and the anode extension portion covers the base layer and the additional electrode.

In a display panel provided by an embodiment of the present invention, the anode extension portion is formed integrally with the anode layer and forms the electrical connecting structure.

In a display panel provided by an embodiment of the present invention, the array substrate further comprises a crack detecting circuit; and

the crack detecting circuit is disposed on the base layer and is configured to detect whether the array substrate has a crack.

In a display panel provided by an embodiment of the present invention, the additional electrode is disposed between the crack detecting circuit and the auxiliary electrode.

Advantages

An array substrate provided by an embodiment of the present invention comprises: a base layer, a thin film transistor, an auxiliary electrode and an additional electrode, the thin film transistor, the auxiliary electrode, and the additional electrode are disposed on the base layer, and the auxiliary electrode is disposed between the thin film transistor and the additional electrode, the auxiliary electrode is electrically connected to the additional electrode by an electrical connecting structure. The present solution can reduce reduces the voltage drop on the auxiliary electrode and increases luminous uniformity of the array substrate.

### DESCRIPTION OF DRAWINGS

FIG. 1 is a first schematic structural view of an array substrate provided by an embodiment of the present invention.

FIG. 2 is a schematic structural view of a base layer of an array substrate provided by an embodiment of the present invention.

FIG. 3 is a second schematic structural view of an array substrate provided by an embodiment of the present invention.

FIG. 4 is a third schematic structural view of an array substrate provided by an embodiment of the present invention.

FIG. 5 is a fourth schematic structural view of an array substrate provided by an embodiment of the present invention.

FIG. 6 is a schematic structural view of a display panel provided by an embodiment of the present invention.

### DETAILED DESCRIPTION OF PREFERRED EMBODIMENTS

The technical solution in the embodiment of the present invention will be clearly and completely described below with reference to the accompanying drawings in the embodiments of the present invention. Apparently, the described embodiments are merely some embodiments of the present invention instead of all embodiments. According to the embodiments in the present invention, all other embodiments obtained by those skilled in the art without making any creative effort shall fall within the protection scope of the present invention.

An embodiment of the present invention provides an array substrate and a display panel, which will be described respectively as follows.

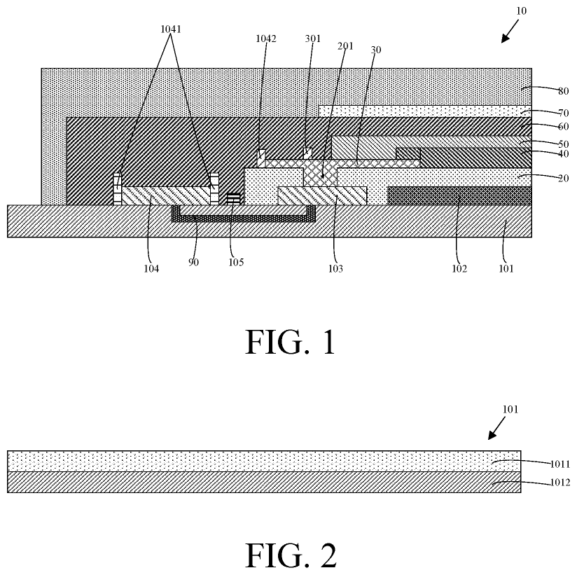

With reference to FIG. 1, FIG. 1 is a first schematic structural view of an array substrate provided by an embodiment of the present invention. The array substrate 10 can comprise a base layer 101, a thin film transistor 102, an auxiliary electrode 103, an additional electrode 104, a planarization layer 20, and an anode layer 30.

The thin film transistor 102, the auxiliary electrode 103 and the additional electrode 104 are disposed on the base layer 101. The auxiliary electrode 102 is disposed between the thin film transistor 102 and the additional electrode 104.

It should be note that the thin film transistor 102 is disposed on an edge of the base layer 101. The thin film transistor can be a low temperature polysilicon thin film transistor, an oxide semiconductor thin film transistor, a solid phase crystallization thin film transistor, or other known thin film transistor often used for display technologies.

The auxiliary electrode 103 is a VSS signal wire. A typical value of the auxiliary electrode 103 is about 100 microns. It should be noted that the additional electrode 102 is a newly added VSS signal wire for preventing the issue of uneven luminescence of the array substrate 10 resulting from increased voltage drop due to the decreased width of the auxiliary electrode 103. It should be understood that to achieve the above technical effect, electrically connecting the auxiliary electrode 103 to the additional electrode 104 is necessary. Therefore, an electrical connecting structure 90 can be disposed to electrically connect the auxiliary electrode 103 to the additional electrode 104 by the electrical connecting structure 90.

The planarization layer 20 is disposed on the thin film transistor 102, the auxiliary electrode 103, and the base layer 101. Furthermore, a via hole 201 is defined in the planarization layer 20 and exposes the auxiliary electrode 102.

The anode layer 30 is disposed on the planarization layer 20 and is connected to the auxiliary electrode 103 through the via hole 201 in the planarization layer 20.

In some embodiments, with reference to FIG. 2, the base layer 101 can comprises a base substrate 1011 and an inorganic insulation layer 1012. The inorganic insulation layer 1012 is disposed on the base substrate 1011. The electrical connecting structure 90 can be covered and disposed in the inorganic insulation layer 1012. It should be explained that material of the electrical connecting structure 90 can be aluminum (Al), molybdenum (Mo), copper (Cu), and silver (Ag), etc.

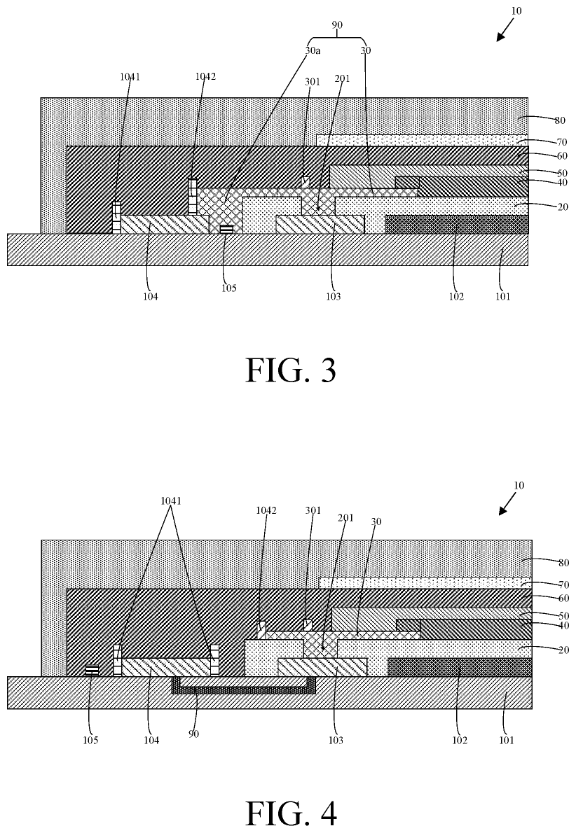

In an embodiment of the present invention, the array substrate 10 can further comprise a crack detecting circuit 105. The crack detecting circuit 105 is disposed on the base layer, and can be configured to detect whether the array substrate 10 has a crack. With reference to FIG. 1 or 3 specifically, the crack detecting circuit 105 can be disposed between the auxiliary electrode 103 and the additional electrode 104. It should be noted that the crack detecting circuit 105 can detect whether a side of the crack detecting circuit 105, the auxiliary electrode 103, and the thin film transistor 102 has a crack, but cannot detect whether a side of the additional electrode 104 has a crack. When a side of the additional electrode 104 has a crack that cannot be detected, performance of the array substrate 10 may be influenced.

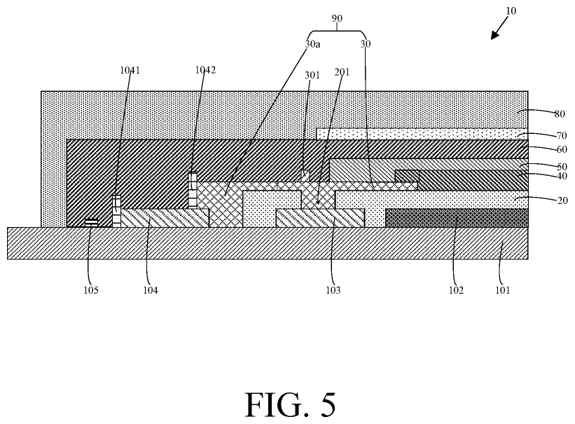

To prevent the above circumstance, the additional electrode 104 can be disposed between the crack detecting circuit 105 and the auxiliary electrode 103. In other words, the thin film transistor 102, the auxiliary electrode 103, and the additional electrode 104 are disposed on a side, the crack detecting circuit 105 is disposed on another side, as shown specifically in FIG. 4 or 5.

It should be noted that sides of the additional electrode 104 and the anode layer 30 are easily corroded. Therefore, a blocking wall can be disposed on the sides of the additional electrode 104 and the anode layer 30. Specifically, with reference FIG. 4, a first blocking wall 1041 can be disposed on the side of the additional electrode 104 near the crack detecting circuit 105 and a first blocking wall 1041 can be disposed on the side of the additional electrode 104 near the auxiliary electrode 103. A second blocking wall 1042 can be disposed the side of the anode layer 30 near the additional electrode 104. It should be noted that a thickness of the first blocking wall 1041 is greater than a thickness of the additional electrode 104, and a thickness of the second blocking wall 1042 is greater than a thickness of a portion of the anode layer 30 on the planarization layer 20.

In some embodiments, with reference to FIG. 3 or 5, the array substrate 10 can further comprise an anode extension portion 30a. The anode extension portion 30a is disposed on a side of the anode layer 30 near the additional electrode 104 a side and extends along a direction toward the additional electrode 104. The anode extension portion 30a covers the base layer 101 and the additional electrode 104. The anode extension portion 30a can has the same material used for forming the anode layer 30 and can be formed integrally with the anode layer 30 and form the electrical connecting structure 90.

It can be understood that because the side of the additional electrode 104 near the auxiliary electrode 103 is covered by the anode extension portion 30a, there is no need to dispose a blocking wall on the side. Therefore, the first blocking wall 1041 can be disposed on the side of the additional electrode 104 near the crack detecting circuit 105, and the second blocking wall 1042 can be disposed on the side of the anode extension portion 30a near the additional electrode 104 to prevent the sides of the anode extension portion 30a and the additional electrode 104 from corrosion, as shown in FIG. 5.

In an embodiment of the present invention, the array substrate 10 can further comprise a cathode layer 40, a pixel definition layer 301, an AMOLED functional layer 50, a first encapsulation layer 60, a second encapsulation layer 70, and a third encapsulation layer 80.

The cathode layer 40 is disposed on the planarization layer 20 and the anode layer 30. The pixel definition layer 301 is disposed on the anode layer 30. The AMOLED functional layer 50 covers the cathode layer 40 and a portion of the anode layer 30. The first encapsulation layer 60 covers the AMOLED functional layer 50, the pixel definition layer 301, the anode layer 30, the additional electrode 104, and the base layer 101. The second encapsulation layer 70 is disposed on the first encapsulation layer 60. The third encapsulation layer 80 covers the second encapsulation layer 70, the first encapsulation layer 60, and the base layer 101.

It should be noted that the first encapsulation layer 60 and the third encapsulation layer 80 are inorganic encapsulation layers. The second encapsulation layer 70 is an organic encapsulation layer.

As described above, an array substrate provided by an embodiment of the present invention 10, by adding an additional electrode 104 on the base layer 101 of the array substrate and electrically connecting the auxiliary electrode 103 and the additional electrode 104 through an electrical connecting structure 90, can prevent difference of luminous uniformity of the array substrate 10 resulting from due to voltage drop caused by the decreased width of the auxiliary electrode 104 such that luminous uniformity of the array substrate 10 is improved.

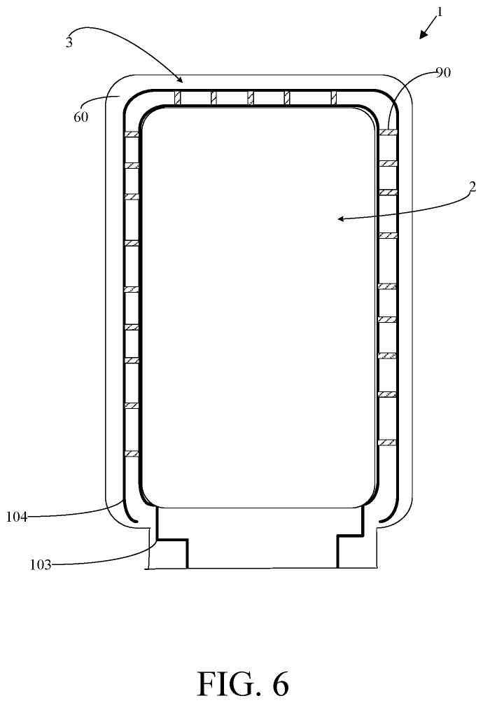

The array substrate 10 provided by the above embodiment can be included in a display panel 1. With reference to FIG. 6, the display panel 1 can comprise a displaying region 2 and a non-displaying region 3. The auxiliary electrode 103, the additional electrode 104, the electrical connecting structure 90, and the first encapsulation layer 60 are disposed in the non-displaying region 3.

In the above embodiments focuses on description of each embodiment. Description omitted in some embodiment can refer to related description in other embodiment.

As described above, an array substrate provided by an embodiment of the present invention has been introduced in details. In the specification, the specific examples are used to explain the principle and implementation of the present invention. The above description is only used to help understand the technical solution of the present invention and the core spirit thereof. A person having ordinary skill in the art should understand that he/her can still modify the technical solutions described in the foregoing embodiments, or replace some of the technical features with equivalents. Such modification or replacement would not make the nature of corresponding technical solution depart from the scope of the technical solution of each embodiment of the present invention.

What is claimed is:

1. An array substrate, comprising: a base layer, a thin film transistor, an auxiliary electrode, and an additional electrode; and
the thin film transistor, auxiliary electrode and the additional electrode disposed on the base layer, the auxiliary electrode disposed between the thin film transistor and the additional electrode, and the auxiliary electrode connected to the additional electrode by an electrical connecting structure.

2. The array substrate as claimed in claim 1, wherein the base layer comprises a base substrate and an inorganic insulation layer, the inorganic insulation layer is disposed on the base substrate.

3. The array substrate as claimed in claim 2, wherein the electrical connecting structure is covered and disposed in the inorganic insulation layer.

4. The array substrate as claimed in claim 1, wherein the array substrate further comprises:
a planarization layer, the planarization layer disposed on the thin film transistor, the auxiliary electrode, and the base layer, and a via hole defined in the planarization layer and exposing the auxiliary electrode; and
an anode layer, the anode layer disposed on the planarization layer and connected to the auxiliary electrode through the via hole.

5. The array substrate as claimed in claim 4, wherein the array substrate further comprises an anode extension portion; and
the anode extension portion is disposed on a side of the anode layer near the additional electrode and extends along a direction toward the additional electrode, and the anode extension portion covers the base layer and the additional electrode.

6. The array substrate as claimed in claim 5, wherein the anode extension portion is formed integrally with the anode layer and forms the electrical connecting structure.

7. The array substrate as claimed in claim 1, wherein the array substrate further comprises a crack detecting circuit; and
the crack detecting circuit is disposed on the base layer and is configured to detect whether the array substrate has a crack.

8. The array substrate as claimed in claim 7, wherein the additional electrode is disposed between the crack detecting circuit and the auxiliary electrode.

9. The array substrate as claimed in claim 8, wherein the array substrate further comprises a first blocking wall;
the first blocking wall is disposed on a side of the additional electrode near the crack detecting circuit and/or on a side of the additional electrode near the auxiliary electrode.

10. The array substrate as claimed in claim 9, wherein a thickness of the first blocking wall is greater than a thickness of the additional electrode.

11. The array substrate as claimed in claim 4, wherein the array substrate further comprises a second blocking wall;
the second blocking wall is disposed on a side of the anode layer toward the additional electrode or on a side of the anode extension portion near the additional electrode.

12. The array substrate as claimed in claim 1, wherein the thin film transistor is located on an edge of the base layer.

13. A display panel, comprising: an array substrate; and
the array substrate comprising a base layer, a thin film transistor, an auxiliary electrode, and an additional electrode, the thin film transistor, auxiliary electrode and the additional electrode disposed on the base layer, the auxiliary electrode disposed between the thin film transistor and the additional electrode, and the auxiliary electrode connected to the additional electrode by an electrical connecting structure.

14. The display panel as claimed in claim 13, wherein the base layer comprises a base substrate and an inorganic insulation layer, and the inorganic insulation layer is disposed on the base substrate.

15. The display panel as claimed in claim 14, wherein the electrical connecting structure is covered and disposed in the inorganic insulation layer.

16. The display panel as claimed in claim 13, wherein the array substrate further comprises:
a planarization layer, the planarization layer disposed on the thin film transistor, the auxiliary electrode, and the base layer, and a via hole defined in the planarization layer and exposing the auxiliary electrode; and
an anode layer, the anode layer disposed on the planarization layer and connected to the auxiliary electrode through the via hole.

17. The display panel as claimed in claim 16, wherein the array substrate further comprises an anode extension portion; and
the anode extension portion is disposed on a side of the anode layer near the additional electrode and extends along a direction toward the additional electrode, and the anode extension portion covers the base layer and the additional electrode.

18. The display panel as claimed in claim 17, wherein the anode extension portion is formed integrally with the anode layer and forms the electrical connecting structure.

19. The display panel as claimed in claim 13, wherein the array substrate further comprises a crack detecting circuit; and
the crack detecting circuit is disposed on the base layer and is configured to detect whether the array substrate has a crack.

20. The display panel as claimed in claim 19, wherein the additional electrode is disposed between the crack detecting circuit and the auxiliary electrode.
